(19) United States
(12) Patent Application Publication
(10) Pub. No.: US 2025/0079314 A1
(43) Pub. Date: Mar. 6, 2025

(54) INTERCONNECT STRUCTURE INCLUDING CONDUCTIVE FEATURE WITH LOW CONTACT RESISTIVITY

(71) Applicant: TAIWAN SEMICONDUCTOR MANUFACTURING COMPANY, LTD., Hsinchu (TW)

(72) Inventors: Hans HSU, Hsinchu (TW); Shu-Wei LI, Hsinchu (TW); Yu-Chen CHAN, Hsinchu (TW); Shin-Yi YANG, Hsinchu (TW); Ming-Han LEE, Hsinchu (TW); Blanka MAGYARI-KOPE, Hsinchu (TW)

(73) Assignee: TAIWAN SEMICONDUCTOR MANUFACTURING COMPANY, LTD., Hsinchu (TW)

(21) Appl. No.: 18/462,151

(22) Filed: Sep. 6, 2023

(51) Int. Cl. H01L 23/532; H01L 23/522

(52) U.S. Cl. CPC H01L 23/53276; H01L 23/5226

(57) ABSTRACT

An interconnect structure includes a conductive feature embedded in a dielectric feature. The conductive feature has a first horizontal portion and a first vertical portion. The first horizontal portion extends in a horizontal direction to terminate at two edge surfaces. The first horizontal portion includes graphene layers stacked on each other, and an intercalation material interposed among the graphene layers. The intercalation material includes a first atom dopant including one of a group 1 metal, a group 2 metal, a group 3 metal, a lanthanide series metal, an actinide series metal, and combinations thereof. The first vertical portion extends in a vertical direction and is in contact with one of the two edge surfaces of the first horizontal portion. The first vertical portion is made of a first electrically conductive metal material.

### BACKGROUND

The integrated circuit (IC) industry aims to enhance interconnect structures, so as to keep contact resistivity of the interconnect structures with, e.g., metal, as low as possible. Novel materials, structures and manufacturing processes are under intense research.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating an interconnect structure in accordance with some embodiments.

FIGS. 2 and 3 are plots of contact resistivity mapping of samples including different intercalation materials in accordance with some embodiments.

FIG. 4 is another contact resistivity mapping of samples including different intercalation materials at different doping amounts in accordance with some embodiments.

FIG. 5 is a graph illustrating atomic radius of different elements and binding energy of the different elements with the graphene layers in accordance with some embodiments.

FIGS. 6 and 7 are schematic diagrams illustrating configuration of the intercalation material in accordance with some embodiments.

FIGS. 8 to 12 are schematic views illustrating intermediate stages of a method for manufacturing the interconnect structure shown in FIG. 1 in accordance with some embodiments.

FIG. 13 is a schematic diagram illustrating another interconnect structure in accordance with some embodiments.

FIGS. 14 to 18 are schematic views illustrating intermediate stages of another method for manufacturing the interconnect structure shown in FIG. 13 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Materials adopted in interconnect structures are desirable to have low contact resistivity when brought into contact with, e.g., a contact metal (such as ruthenium, but is not limited thereto). Graphene intercalated with a metal-including intercalation material is found to have resistivity lower than that of copper, and thus may be considered as a promising alternative material for interconnect structures. The metal-including intercalation material may be a molecular dopant or an atom dopant.

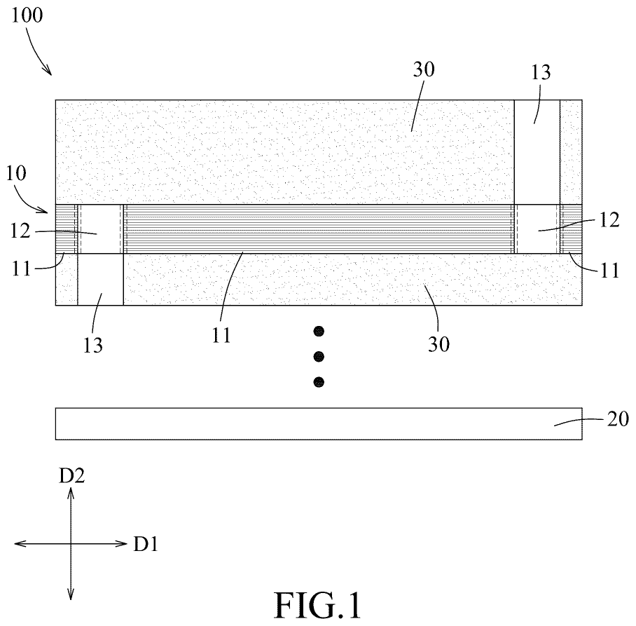

The present disclosure is directed to interconnect structures, e.g., an interconnect structure 100 shown in FIG. 1 and an interconnect structure 200 shown in FIG. 13 in accordance with some embodiments. Some repeating structures are omitted in FIGS. 1 and 13 for the sake of brevity.

Referring to FIG. 1, the interconnect structure 100 is formed in a stack including a substrate 20, a front-end-of-line (FEOL) section (not shown), and a back-end-of-line (BEOL) section (not shown). The interconnect structure 100 is formed in the BEOL section.

The substrate 20 may be made of a low k material. In some embodiments, the substrate may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The material for forming the substrate 20 may be doped with p-type impurities or n-type impurities, or undoped. In addition, the substrate 20 may be a bulk silicon substrate, a silicon-on-insulator (SOI) substrate, or a germanium-on-insulator (GOI) substrate. Other suitable materials for the substrate 20 are within the contemplated scope of disclosure.

The FEOL section may include any suitable elements such as active devices (for example, transistors such as fin-type field-effect transistors (FinFET), nanosheet semiconductor devices (e.g. gate-all-around field-effect transistors (GAAFET), forksheet field-effect transistors, complementary field-effect transistors (CFET), or the like), passive devices (for example, capacitors, resistors, or the like), decoders, amplifiers, other suitable devices, and combinations thereof. Other suitable elements for the FEOL part are within the contemplated scope of disclosure.

The BEOL section may include one or more interconnect structures, such as the interconnect structure 100 shown in FIG. 1, or the interconnect structure 200 shown in FIG. 13. Other suitable components for forming the stack are within the contemplated scope of the present disclosure.

The interconnect structure 100 includes a dielectric feature 30, and a conductive feature 10 embedded in the dielectric feature 30.

The dielectric feature 30 may include a low-k material, carbon-doped hydrogenated silicon oxide (SiOₓC_{y}H_{z}), silicon oxide (SiOₓ), silicon carbon nitride (SiCN), silicon nitride (SiNₓ), silicon carbide (SiC), silicon oxynitride (SiON), carbon-doped silicon oxide (SiOC), oxygen-doped carbide (ODC), nitrogen-doped carbide (NDC), or the like, or combinations thereof. Other suitable materials for forming the dielectric feature 30 are within the contemplated scope of disclosure.

The conductive feature 10 has a first horizontal portion 11, a first vertical portion 12 connected to the first horizontal portion 11, and a second vertical portion 13 connected to the first vertical portion 12. The first horizontal portion 11 extends in a horizontal direction (D1) to terminate at two edge surfaces. The first vertical portion 12 extends in a vertical direction (D2) and is in contact with one of the two edge surfaces of the first horizontal portion 11. The second vertical portion 13 extends away from the first vertical portion 12 in the vertical direction (D2). The vertical direction (D2) is transverse to (e.g., perpendicular to) the horizontal direction (D1).

In some embodiments, the first horizontal portion 11 may have a thickness measured along the vertical direction (D2) ranging from about 0.5 nm to about 40 nm, but is not limited thereto. The first vertical portion 12 may have a width measured along the horizontal direction (D1) ranging from about 6 nm to about 16 nm, but is not limited thereto. Other suitable dimensions for the first horizontal portion 11 and the first vertical portion 12 are within the contemplated scope of disclosure.

Referring to FIG. 1, three first horizontal portions 11, two first vertical portions 12 and two second vertical portions 13 are shown. The three first horizontal portions 11 and the two first vertical portions 12 are connected to each other to serve as a conductive line in the interconnect structure 100. The two second vertical portions 13 serve as conductive vias by respectively extending away from a corresponding one of the first vertical portions 12 in opposite directions so as to electrically interconnect different interconnect levels (not shown) in the BEOL section. For example, the left one of the second vertical portions 13 extends downwardly from the left one of the first vertical portions 12 so as to electrically connect a lower interconnect level (not shown); the right one of the second vertical portions 13 extends upwardly from the right one of the first vertical portions 12 so as to electrically connect an upper interconnect level (not shown).

Please note that number and/or location of each of the first horizontal portions 11, the first vertical portions 12 and the second vertical portions 13 may be determined according to practical needs. Hereinafter, only one first horizontal portion 11 and one first vertical portions 12 are discussed in the following paragraphs.

In some embodiments, each of the first and second vertical portions 12, 13 may be made of an electrically conductive metal material, such as ruthenium, copper, tungsten, titanium, aluminum, cobalt, molybdenum, iridium, rhodium, or the likes, or combinations thereof. Other suitable materials for the first and second vertical portions 12, 13 are within the contemplated scope of disclosure. The first vertical portion 12 may be made of a material same as, or different from that of the second vertical portion 13.

In some embodiments, the first horizontal portion 11 is made of a graphene intercalated compound (GIC). Specifically, the first horizontal portion 11 includes graphene layers that are stacked on each other along the vertical direction (D2), and an intercalation material interposed among the graphene layers. In some embodiments, there are N layers of graphene stacked on one another along the vertical direction, wherein N may be greater than about 100, but is not limited thereto. In other embodiments. N may also be equal to or less than about 100 (e.g., 2≤N≤100). Other ranges of layers of graphene are within the contemplated scope of the present disclosure.

The intercalation material includes atom(s) of metal element(s). In some embodiments, the intercalation material to be and/or intercalated among the graphene layers is the molecular dopant including molecules each having at least one atom of the metal element. For instance, in some embodiments, the molecules may each be a combination of the atom of the metal element and an atom of a non-metal element. In other embodiments, the molecules may each be the atoms of the same metal element (e.g., metallic dimers). In some embodiments, the molecular dopant may be a metal halide, but is not limited thereto. Examples of the molecular dopant include arsenic pentafluoride (AsF₅), antimony pentafluoride (SbF₅), iron (III) chloride (FeCl₃), or the likes, or combinations thereof, but are not limited thereto. In other embodiments, the intercalation material for doping and/or being intercalated among the graphene layers is the atom dopant including the atom(s) of the metal element(s). It is noted that in comparison to the molecular dopant, the atom dopant serving as the intercalating material permits more charges to be transferred to the graphene layers, and a smaller interlayer distance between two adjacent ones of the graphene layers.

In accordance with some embodiments, for the first horizontal portion 11, the intercalation material is the atom dopant. Specifically, the intercalation material may include a first atom dopant, which significantly lowers contact resistivity of the first horizontal portion 11 with the first vertical portion 12. As shown in FIG. 1, each of contact regions between the first horizontal portions 11 and the first vertical portions 12 are indicated by dashed lines. The contact resistivity is measured at the contact regions. Such contact resistivity may also be known as the edge contact resistivity. The first atom dopant may be a group 1 metal (lithium, sodium, potassium, rubidium, caesium, francium), a group 2 metal (beryllium, magnesium, calcium, strontium, barium, radium), a group 3 metal (scandium, yttrium, lutetium, lawrencium), a lanthanide series metal (lanthanum, cerium, praseodymium, neodymium, promethium, samarium, europium, gadolinium, terbium, dysprosium, holmium, erbium, thulium, ytterbium), an actinide series metal (actinium, thorium, protactinium, uranium, neptunium, plutonium, americium, curium, berkelium, californium, einsteinium, fermium, mendelevium, nobelium), or combinations thereof. In some embodiments, the first atom dopant is the group 1 metal, or the group 2 metal, or combinations thereof. In other embodiments, the first atom dopant includes lithium, caesium, rubidium, calcium, sodium, strontium, barium, potassium, or combinations thereof.

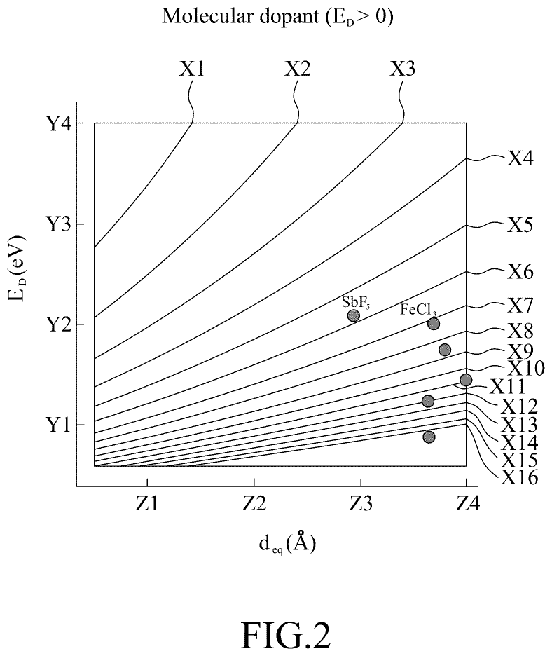

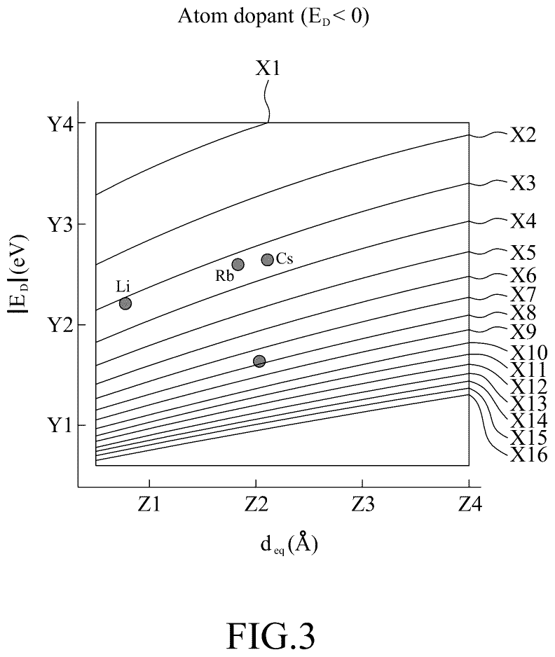

An experiment is conducted on samples of the graphene layers that are intercalated with different intercalation materials. FIGS. 2 and 3 respectively show plots of contact resistivity for the samples that include the molecular dopants as the intercalation material, and the atom dopants as the intercalation material. In each of FIGS. 2 and 3, the labels X1, X2, X3, X4, X5, X6, X7, X8, X9, X10, X11, X12, X13, X14, X15 and X16 are contact resistivity (Re, measured in 10⁻¹¹ Ωcm²) of the samples that are brought into contact with ruthenium (i.e., ruthenium serves as a contact metal, or the first vertical portion 12 as discussed), the y-axis represents Dirac cone energy (E_{D}, measured in eV) of the samples of graphene layers that are intercalated with different intercalation materials, and the x-axis represents an interlayer distance between two adjacent ones of the graphene layers (d_{eq}, measured in Å). Please note that the values of the contact resistivity (R_{c}) increase from X1 to X16 (i.e., X1<X2<X3<X4<X5<X6<X7<X8<X9<X10<X11<X12<X13<X14<X15<X16), the values of the Dirac cone energy (E_{D}) increase from Y1 to Y4 (i.e., Y1<Y2<Y3<Y4), and the values of the interlayer distance (d_{eq}) increase from Z1 to Z4 (i.e., Z1<Z2<Z3<Z4).

As shown in FIG. 2, the molecular dopants, such as antimony pentafluoride (SbF₅) and iron (III) chloride (FeCl₃), are adopted as the intercalation material. The samples including the molecular dopants have the Dirac cone energy (E_{D}) greater than zero, implying that electrons migrate from the molecular dopants to the graphene layers.

As shown in FIG. 3, the atom dopants, such as lithium (Li), rubidium (Ru), caesium (Cs), are adopted as the intercalation material. The samples including the atom dopants have the Dirac cone energy smaller than zero, implying that electrons migrate from the graphene layers to the atom dopants. In FIG. 3, the negative Dirac cone energy for each atom dopant is expressed by an absolute value thereof (i.e., |E_{D}|).

Comparing FIGS. 2 and 3, it is noted that that the samples including the atom dopants have contact resistivity (R_{c}) even smaller than those of the samples including the molecular dopants. In addition, the absolute value of the Dirac cone energy (E_{D}) for each of the samples including the atom dopants is greater than that for each of the samples including the molecular dopants. Moreover, the interlayer distance (d_{eq}) for each of the samples including the atom dopants is smaller than that of each of the samples including the molecular dopants.

Contact resistivity (R_{c}) is proportional to reciprocal of square root of Dirac cone energy (E_{D}) (i.e., R_{c} ∝1/√E_{D}). That is, a larger absolute value of the Dirac cone energy (E_{D}) results in a smaller contact resistivity (R_{c}), as more charge carriers are present around the Fermi energy level. In addition, contact resistivity (R_{c}) is proportional to the interlayer distance (d_{eq}) (i.e., R_{c} ∝d_{eq}). In view of the above, the samples including the atom dopants have a comparatively greater Dirac cone energy (E_{D}) and a comparatively smaller interlayer distance (d_{eq}), and thus may achieve a comparatively lower contact resistivity (R_{c}).

First atoms of the first atom dopant are interposed among the graphene layers by being distributed in a space between any two adjacent ones of the graphene layers. In some embodiments, between two adjacent ones of the graphene layers, the first atoms are arranged as a single atomic layer. That is, between two adjacent ones of the graphene layers, there is only one atomic layer of the first atoms along the vertical direction (D2, i.e., the stacking direction of the graphene layers), and the first atoms (of the single atomic layer) of the first atom dopant are considered lying on a same plane. In such case, there are no piling up of the first atoms along the vertical direction (D2) between two adjacent graphene layers, and thus the interlayer distance between two adjacent ones of the graphene layers could be kept as small as possible, so as to keep the contact resistivity at a relatively low level.

The first atom dopant may have a wide doping density range. In some embodiments, the first atom dopant may have a relatively low doping density that the first atoms are non-interacting with each other. That is, in certain embodiments, an in-between distance between two adjacent ones of the first atoms may be greater than approximately 20 Å. In other embodiments, the first atom dopant is present with a doping density of approximately one to three of the first atom(s) per 4 to 5 nm² of the first horizontal portion 11. Other density ranges are within the contemplated scope of the present disclosure.

In some other embodiments, the first atom dopant may have a maximum doping density that (i) the in-between distance between two adjacent ones of the first atoms may be not greater than a bulk bond length of atoms that are present in a bulk and that are of the same element as the first atoms of the first atom dopant, and that (ii) all the first atoms between two adjacent graphene layers are aligned on the same plane. As such, the first atoms are intercalated among the graphene layers at the maximum doping density, without increasing the interlayer distance between two adjacent graphene layers, so as to keep the contact resistivity at a relatively low level. For example, when the first atoms are caesium atoms, the in-between distance between two adjacent ones of the caesium atoms between two adjacent ones of the graphene layers is not greater than a bulk bond length of caesium atoms that are present in a bulk of caesium metal. For example, when the first atoms are caesium atoms and lithium atoms, the in-between distance between two adjacent ones of the caesium atoms and the lithium atoms between two adjacent ones of the graphene layers is not greater than an average bond length of caesium atoms and lithium atoms that are present in a bulk metal of caesium and lithium. The average bond length refers to, in the bulk metal of caesium and lithium, an average of bond lengths of (a) two of the caesium atoms (b) two of the lithium atoms, and (c) one of the caesium atoms and one of the lithium atoms). In addition, a ratio of an amount of the caesium atoms to an amount of the lithium atoms (of the first atom dopant) is substantially the same as a ratio of an amount of the caesium atoms to an amount of the lithium atoms (in the bulk metal of caesium and lithium).

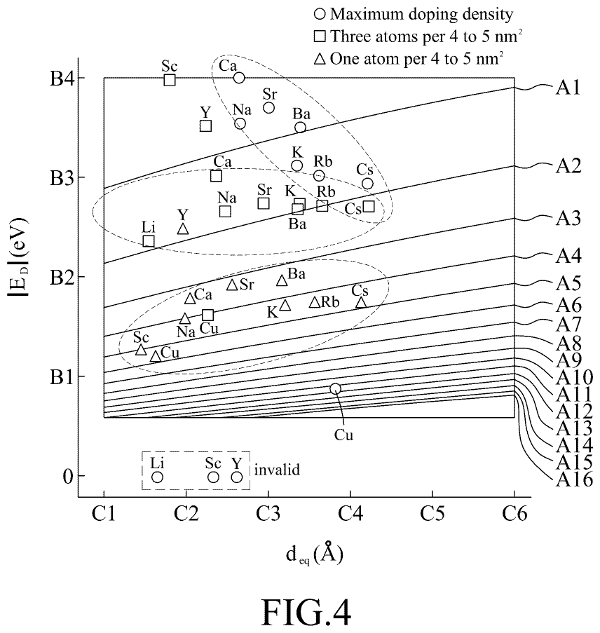

A high-throughput screening is conducted on different samples of graphene layers that are intercalated with different atom dopants, and at different doping amounts (different doping densities). FIG. 4 shows the contact resistivity measured in these samples. The atom dopants adopted in the high-throughput screening are group 1 metal, group 2 metal, group 3 metal, and copper. The atom dopants are respectively intercalated into the graphene layers respectively at greatest amount with a maximum doping density (following the criteria (i) and (ii) mentioned above), and at comparatively smaller doping amount with low doping density (such as intercalating only one atom, or three atoms of the atom dopants per 4 to 5 nm², to the samples of graphene layers). Please note that the values of the contact resistivity (R_{c}) increase from A1 to A16 (i.e., A1<A2<A3<A4<A5<A6<A7<A8<A9<A10<A11<A12<A13<A14<A15<A16), the absolute values of the Dirac cone energy (E_{D}) increase from 0 to B4 (i.e., 0<B1<B2<B3<B4), and the values of the interlayer distance (d_{eq}) increase from C1 to C6 (i.e., C1<C2<C3<C4<C5<C6).

As shown in FIG. 4, for samples including group 1 metal atom dopants, group 2 metal atom dopants, and group 3 metal atom dopants, in general, those having greater doping amounts achieve contact resistivity lower than those having smaller doping amounts. That is, group 1 metal atom dopants, group 2 metal atom dopants, and group 3 metal atom dopants may achieve the lowest contact resistivity at their maximum doping densities. In addition, the samples having greater doping amount generally have greater absolute values of the Dirac cone energy (E_{D}). It is noted that, when copper atom, which is neither a group 1, a group 2, nor a group 3 metal, is adopted as the atom dopant, the samples thereof generally have less satisfactory contact resistivity for the different doping amounts examined. In addition, in comparison with the samples doped with the copper atom dopant at different doping density, the sample doped with the copper atom dopant at maximum doping density does not achieve the lowest contact resistivity, or the greatest absolute value of the Dirac cone energy (E_{D}).

In some embodiments, the intercalation material may further include a second atom dopant that serves as a co-doping species with the first atom dopant. The second atom dopant is also a metal dopant that has a size comparatively larger (larger atomic radius) than that of the first atom dopant, and/or, that has a binding energy with the graphene layers comparatively greater than a binding energy between the first atom dopant and the graphene layers. The inclusion of the second atom dopant helps to block movement of the first atom dopant and thus stabilizes the first atom dopant (which is relatively mobile and less stable) within the graphene layers. In some embodiments, the second atom dopant may be one of cobalt, chromium, vanadium, ruthenium, scandium, osmium, technetium, rhenium, tungsten, niobium, tantalum, hafnium, yttrium, and combinations thereof.

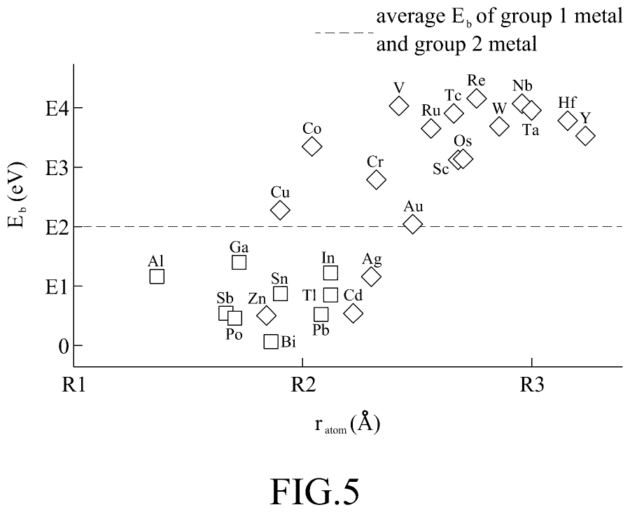

FIG. 5 illustrates the binding energy (E_{b}, measured in eV) between different metal species and the graphene layers, as well as the atomic radius (rₐₜₒₘ, measured in Å) of the different metal species in accordance with some embodiments. Please note that the values of the binding energy (E_{b}) increase from 0 to E4 (i.e., 0<E1<E2<E3<E4), and the values of the atomic radius (rₐₜₒₘ) increase from R1 to R3 (i.e., R1<R2<R3). An average binding energy between metals (including group 1 metal and group 2 metal) and the graphene layers is represented by the dashed line. Referring to FIG. 5, the metal species located above the dashed line may serve as the second atom dopant, and such metal species, which are farther away from the dashed line, may have a comparatively greater binding energy with the graphene layers. It is shown that metal species that have comparatively greater size (i.e, species having larger atomic radius (rₐₜₒₘ) as shown in FIG. 5) also have comparatively greater binding strength (i.e., the higher binding energy (E_{b})) with the graphene layers, making such metal species ideal to serve as the co-doping species to the first atom dopant for blocking movement of the first atom dopant.

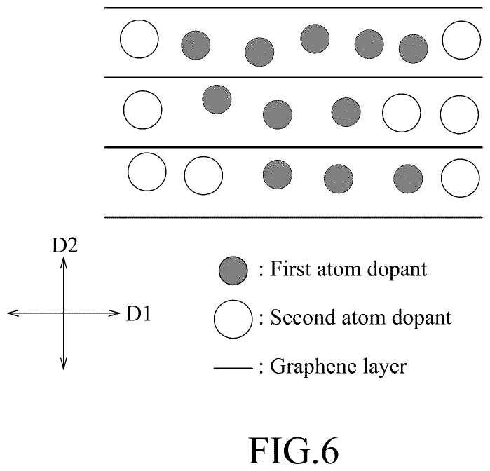

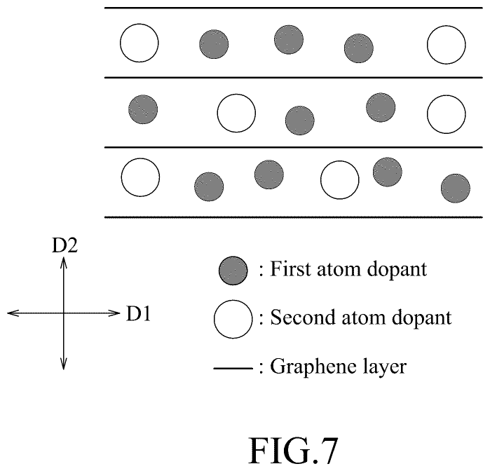

FIGS. 6 and 7 illustrates different doping schemes of the first atom dopant and the second atom dopant in two adjacent one of the graphene layers in accordance with some embodiments. The smaller circles represent the first atoms of the smaller size first atom dopant. The large circles represent second atoms of the larger size second atom dopant. The straight lines represent the graphene layers.

FIG. 6 is a schematic view of a cross-section of the graphene layers and the intercalation material along the vertical direction (D2, i.e., along the stacking direction of the graphene layers), illustrating a boundary-type doping scheme. The space between any two adjacent ones of the graphene layers includes a central region, and a boundary region surrounding the central region. The first atoms of the first atom dopants are disposed on the central region, while the second atoms of the second atom dopant are disposed on the boundary region, so as to surround and enclose the first atoms of the first atom dopant within the space between adjacent graphene layers. In some embodiments, in order to reach such configuration, when introducing the intercalation material into the graphene layers, the first atom dopant is first introduced, followed by a subsequent process to introduce the second atom dopant. As such, compared to the first atom dopant, the second atom dopant are less mobile and has higher binding strength with the graphene layers, and most likely will take up the boundary region.

FIG. 7 is another schematic view of a cross-section of the graphene layers and the intercalation material along the vertical direction, illustrating a mix-type doping scheme. Within the space between any two adjacent ones of the graphene layers, regardless of whether it is the central region or the boundary region, the first atoms of the first atom dopant and the second atoms of the second atom dopant are randomly distributed. That is, both the first atom dopant and the second dopant may be present in each of the central region and the boundary region. Other doping schemes of the first atom dopant and the second atom dopant are within the contemplated scope of the present disclosure. One may freely determine to adopt which doping scheme according to practical needs.

Please note that, regardless of the first atom dopant alone, or both the first and second atom dopants together serving as the intercalation material, in some embodiments, between two adjacent graphene layers, the first and second atoms of the intercalation material are arranged as a single atomic layer, i.e., the first and second atoms do not pile up along the vertical direction (D2), so as to keep the interlayer distance small, and to achieve a low contact resistivity.

In the case that the first and second atom dopants together serve as the intercalation material, the second atom dopant may have an atomic concentration ranging from about 10% to about 30% based on a total amount of the first and second atoms. In addition, in order to achieve a low contact resistivity, the intercalation material (both the first atom dopant and the second atom dopant) may have a maximum doping density determined similar to the criteria (i) and (ii) mentioned above. That is, for (i), between two adjacent ones of the graphene layers, two adjacent ones of the first atoms and the second atoms are spaced apart by an in-between distance. The in-between distance is not greater than an average bond length of third atoms and fourth atoms that are present in a bulk, in which the third atoms are of the same element as the first atoms, and the fourth atoms are of the same element as the second atoms. The average bond length refers to, in the bulk of the third and fourth atoms, an average of bond lengths of (a) two of the third atoms (b) two of the fourth atoms, and (c) one of the third atoms and one of the fourth atoms). In addition, a ratio of an amount of the first atoms to an amount of the second atoms (of the interaction material) is substantially the same as a ratio of an amount of the third atoms to an amount of the fourth atoms (in the bulk). For (ii), all the first atoms and the second atoms between two adjacent graphene layers are aligned on the same plane.

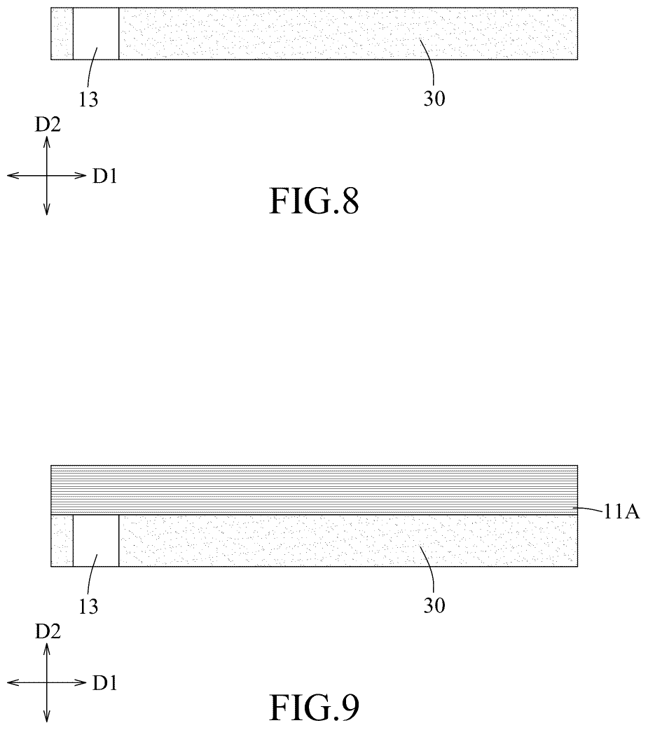

FIGS. 8 to 12 illustrate schematic views of intermediate stages of a method for preparing the interconnect structure 100 shown in FIG. 1 in accordance with some embodiments. Additional steps can be provided before, after or during the method, and some of the steps described herein may be replaced by other steps or be eliminated. The method includes the following steps.

Referring to FIG. 8, the second vertical portion 13 is formed in a lower part of the dielectric feature 30. For instance, a dielectric material layer (not shown, for forming the lower part of the dielectric feature 30) is formed over the substrate 20 (see FIG. 1) by one or more deposition processes (such as chemical vapour deposition (CVD), atomic layer deposition (ALD), other suitable processes, or combinations thereof). An opening (not shown) is formed in the dielectric material layer so as to form the lower part of the dielectric feature 30 and to expose a conductive portion (not shown) of a lower interconnect structure (not shown) underneath. A first electrically conductive metal material layer (not shown, for forming the lower second vertical portion 13) is deposited over the lower part of the dielectric feature 30 to fill the opening, followed by performing one or more planarization processes (such as, chemical-mechanical polishing (CMP), or other suitable processes) over the first electrically conductive metal material layer, thereby forming the lower second vertical portion 13 exposed from the lower part of the dielectric feature 30.

Referring to FIG. 9, a stack 11A of the graphene layers is formed over the lower part of the dielectric feature 30 and the lower second vertical portion 13. The graphene layers may be formed by one or more deposition processes, such as CVD, or other suitable processes, or combinations thereof, but are not limited thereto.

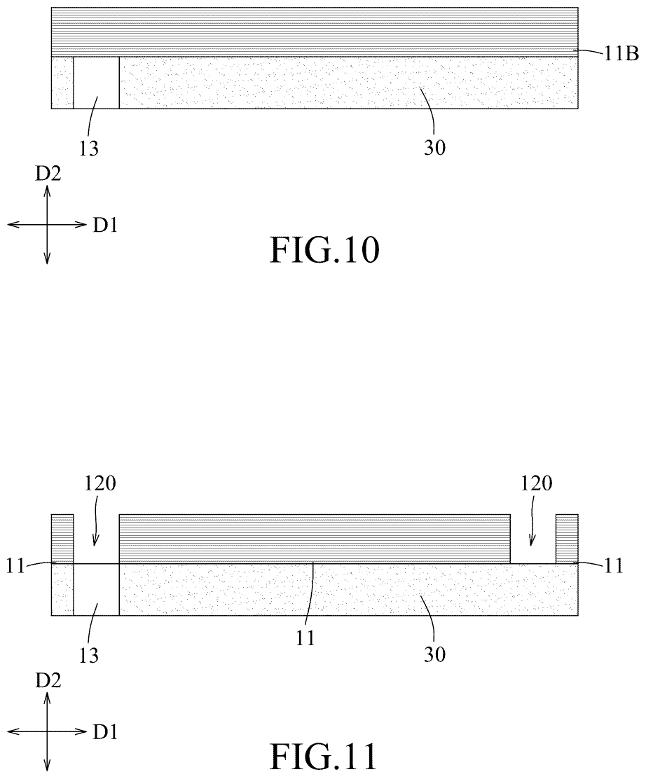

Referring to FIGS. 9 and 10, the stack 11A of the graphene layers is then subjected to an intercalation process, such that the intercalation material is intercalated to interpose among the graphene layers, and the stack 11A becomes an intercalated stack 11B. Any suitable intercalation processes known in the art may be applied, such as using a supercritical fluid (SCF) technique, an electroplating process, an electrochemical process, but are not limited thereto. In some embodiments, the SCF technique may be applied. For instance, the intercalation material and the structure shown in FIG. 9 are placed in a system that is adjusted to have a temperature gradient across the intercalant and the structure. Argon, but is not limited thereto, is introduced into the system in a controlled manner through a mass flow controller so as to permit the intercalation material to flow with the argon and to be introduced among the graphene layers. Parameters for performing the intercalation, such as the supercritical fluid applied, flow rate thereof, temperature gradients and any other suitable parameters, may be adjusted according to practical needs. Other suitable methods for forming the intercalated stack 11B are within the contemplated scope of the present disclosure, as long as the graphene layers will not be damaged.

Referring to FIGS. 10 and 11, two through holes 120 are formed in the intercalated stack 11B using suitable processes (such as a photolithography process and a suitable etching process, but not limited thereto), such that the intercalated stack 11B is formed into three the first horizontal portions 11. Please note that number of the through holes 120 correspond to number of the first vertical portions 12. In some embodiments, the through holes 120, expose sidewalls of the first horizontal portions 11. The right one of the through holes 120 exposes a portion of an upper surface of the lower part of the dielectric feature 30. The left one of the through holes 120 expose an upper surface of the lower second vertical portion 13. In some embodiments, a treatment may be performed to prevent mobile intercalating material from leaking out of the graphene layers through the sidewalls of the first horizontal portions 11.

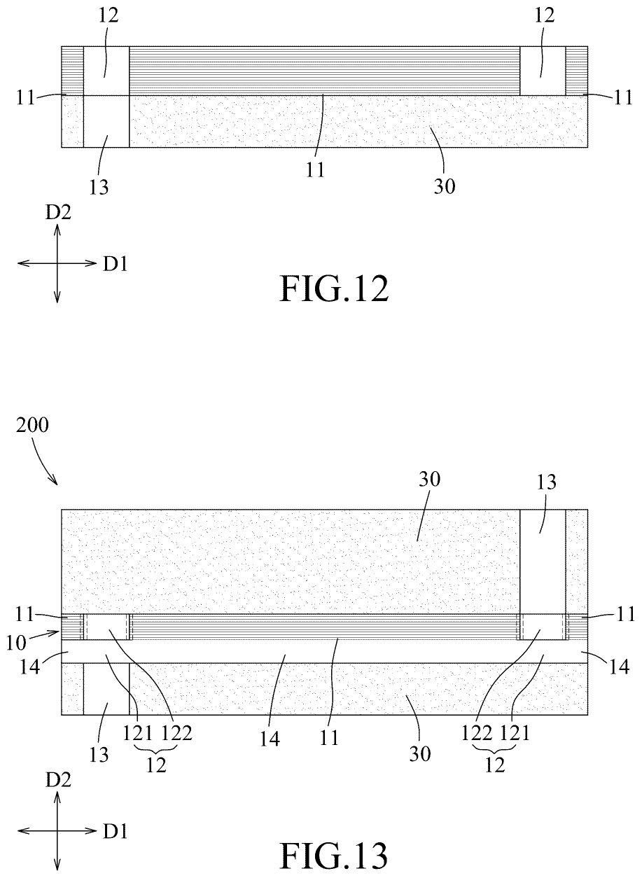

Referring to FIGS. 11 and 12, a second electrically conductive metal material layer (not shown, for forming the first vertical portions 12) is deposited over the first horizontal portions 11 to fill the through holes 120, followed by performing one or more planarization processes (such as, CMP, or other suitable processes) over the second electrically conductive metal material layer, thereby forming the first vertical portions 12 exposed from the first horizontal portions 11.

Referring to FIGS. 12 and 1, an upper part of the dielectric feature 30 is formed over the first vertical portions 12 and the first horizontal portions 11 opposite to the substrate 20 as shown in FIG. 1, and the upper second vertical portion 13 is formed in the upper part of the dielectric feature 30, thereby obtaining the interconnect structure 100. Formation of the upper part of the dielectric feature 30 and the upper second vertical portion 13 may be performed using processes similar to those described with reference to FIG. 8, and thus details thereof are omitted for the sake of brevity.

FIG. 13 illustrates the interconnect structure 200 which is similar to the interconnect structure 100 shown in FIG. 1, except that the conductive feature 10 further includes a second horizontal portion 14 that is disposed on the first horizontal portion 11, and that is in contact with the first vertical portion 12.

Specifically, the first horizontal portion 11 has an upper surface and a lower surface opposite to the upper surface in the vertical direction (D2). The second horizontal portion 14 is in contact with one of the upper surface and the lower surface of the first horizontal portion 11. The second horizontal portion 14 extends in the horizontal direction (D1), and is in contact with a lower part 121 of the first vertical portion 12. That is, in the interconnect structure 200, a side surface of an upper part 122 of the first vertical portion 12 may be in contact with the first horizontal portion 11, and a side surface of the lower part 121 of the first vertical portion 12 may be in contact with the second horizontal portion 14. In some embodiments, the second horizontal portion 14 may have a thickness ranging from about 0.5 nm to about 40 nm, but is not limited thereto. Other thickness ranges for forming the second horizontal portion 14 are within the contemplated scope of the present disclosure.

Materials for the second horizontal portion 14 are similar to those of the first vertical portion 12, and details thereof are omitted for the sake of brevity. The second horizontal portion 14 may be made of a material same as, or different from that of the first vertical portion 12 and/or the second vertical portion 13. Other materials for forming the second horizontal portion 14 are within the contemplated scope of the present disclosure.

Referring to FIG. 13, three second horizontal portions 14 are shown. In some embodiments, the second horizontal portions 14 are respectively in contact with the lower surfaces of the three first horizontal portions 11. In other embodiments, the second horizontal portions 14 may be disposed on the upper surfaces of the first horizontal portions 11. The first horizontal portions 11, the second horizontal portions 14 and the first vertical portions 12 are connected to each other to serve as a conductive line in the interconnect structure 200. The two second vertical portions 13 are respectively disposed on the first vertical portions 12 and extend away therefrom in opposite directions. The right second vertical portion 13 is disposed proximal to the first horizontal portions 11. The left second vertical portion 14 is disposed proximal to the second horizontal portions 14. Other configurations of the conductive feature 10 are within the contemplated scope of the present disclosure.

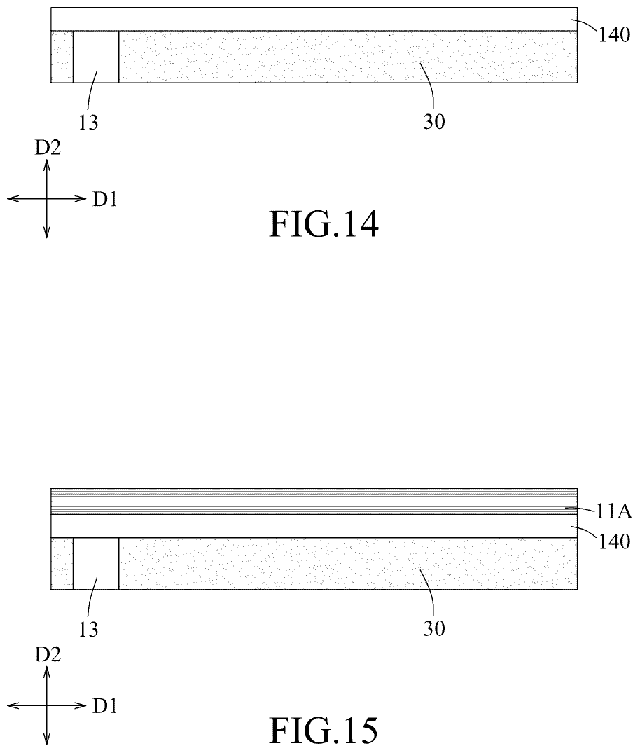

FIGS. 14 to 18 illustrate schematic views of intermediate stages of another method for preparing the interconnect structure 200 shown in FIG. 13 in accordance with some embodiments. Additional steps can be provided before, after or during the method, and some of the steps described herein may be replaced by other steps or be eliminated. The method includes the following steps.

The lower second vertical portion 13 and the lower part of the dielectric feature 30 are formed in a manner similar to that described with reference to FIG. 8, and details thereof are omitted for the sake of brevity.

Referring to FIG. 14, a material layer 140 for serving as the second horizontal portions 14 (see FIG. 13) and lower parts 121 of the first vertical portions 12 is formed over the lower second vertical portion 13 and the lower part of the dielectric feature 30 by one or more deposition processes (such as CVD, ALD, other suitable processes, or combinations thereof).

Referring to FIG. 15, the stack 11A of the graphene layers is formed over the material layer 140. The graphene layers may be formed by one or more deposition processes, such as CVD, or other suitable processes, or combinations thereof, but are not limited thereto.

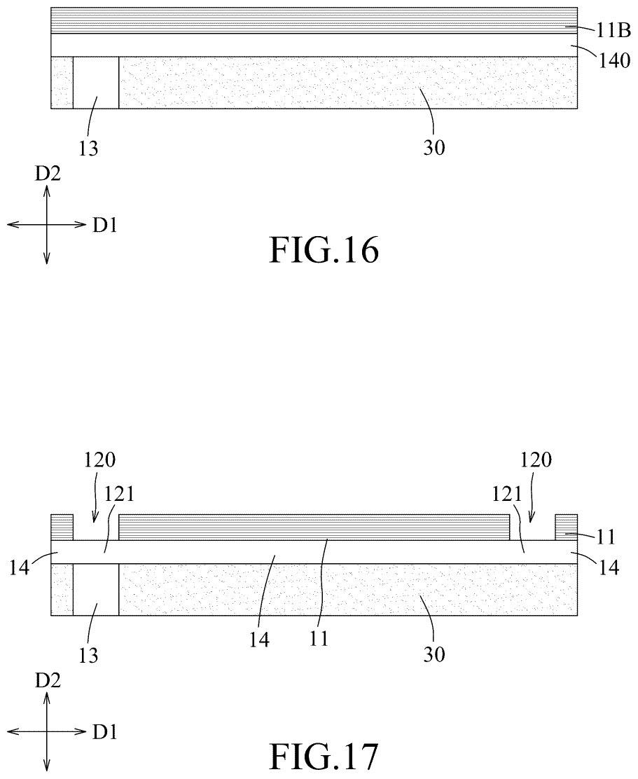

Referring to FIGS. 15 and 16, the stack 11A is subjected to an intercalation process, such that the intercalation material is intercalated to interpose among the graphene layers, and the stack 11A becomes an intercalated stack 11B. The intercalation process is similar to that described with reference to FIG. 10, and details thereof are omitted for the sake of brevity.

Referring to FIGS. 16 and 17, two through holes 120 are formed in the intercalated stack 11B, such that the intercalated stack 11B is formed into three the first horizontal portions 11. In FIG. 17, the through holes 120 expose sidewalls of the first horizontal portions 11 and portions of an upper surface of the material layer 140. Portions of the material layer 140 that have the upper surfaces exposed serve as the lower parts 121 of the first vertical portions 12, and another portions of the material layer 140 that have the upper surfaces unexposed serve as the second horizontal portions 14. Formation of the through holes 120 are similar to that described with reference to FIG. 11, and details thereof are omitted for the sake of brevity.

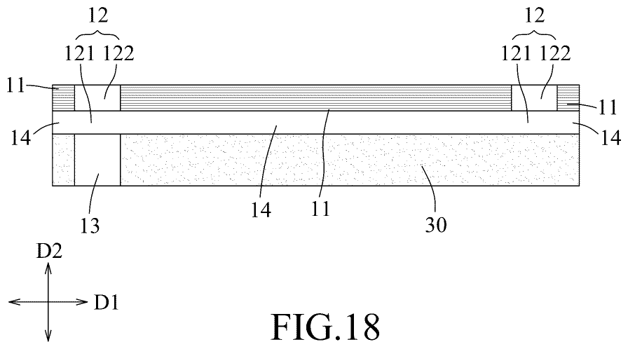

Referring to FIGS. 17 and 18, upper parts 122 of the first vertical portions 12 are formed in the through holes 120 using processes similar to those described with reference to FIG. 12, and details thereof are omitted for the sake of brevity.

Referring to FIGS. 18 and 13, the upper part of the dielectric feature 30 is formed over the first vertical portions 12 and the first horizontal portions 11 opposite to the second horizontal portions 14 as shown in FIG. 13, and the upper second vertical portion 13 is formed in the upper part of the dielectric feature 30, thereby obtaining the interconnect structure 200. Formation of the upper part of the dielectric feature 30 and the upper second vertical portion 13 may be performed using processes similar to those described with reference to FIG. 8, and thus details thereof are omitted for the sake of brevity.

The embodiments of the present disclosure have the following advantageous features. The stack of graphene layers intercalated with the first atom dopant can achieve a relatively low contact resistivity. The second atom dopant, which has larger size and greater binding energy with the graphene layers, serves as the co-doping species to stabilize the first atom dopant within the graphene layers. The contact resistivity may be further reduced when maximum doping density of the intercalating material is reached. Such graphene layers, having low contact resistivity, serve as a promising material to be used in the interconnect structure, so as to reduce energy consumption of the interconnect structure.

In accordance with some embodiments of the present disclosure, an interconnect structure includes a conductive feature embedded in a dielectric feature and having a horizontal portion which includes graphene layers stacked on each other; and a metal-including intercalation material interposed among the graphene layers.

In accordance with some embodiments of the present disclosure, the metal-including intercalation material includes a first atom dopant having one of a group 1 metal, a group 2 metal, a group 3 metal, a lanthanide series metal, an actinide series metal, and combinations thereof.

In accordance with some embodiments of the present disclosure, the first atom dopant includes one of lithium, caesium, rubidium, calcium, sodium, strontium, barium, potassium, and combinations thereof.

In accordance with some embodiments of the present disclosure, between two adjacent ones of the graphene layers, first atoms of the first atom dopant are arranged as a single atomic layer.

In accordance with some embodiments of the present disclosure, two adjacent ones of the first atoms between two adjacent ones of the graphene layers are spaced apart by an in-between distance which is not greater than a bulk bond length of atoms that are present in a bulk and that are of the same element as the first atoms.

In accordance with some embodiments of the present disclosure, the metal-including intercalation material further includes a second atom dopant, a binding energy between the second atom dopant and the graphene layers being greater than a binding energy between the first atom dopant and the graphene layers.

In accordance with some embodiments of the present disclosure, the second atom dopant includes one of cobalt, chromium, vanadium, ruthenium, scandium, osmium, technetium, rhenium, tungsten, niobium, tantalum, hafnium, yttrium, and combinations thereof.

In accordance with some embodiments of the present disclosure, the second atom dopant has an atomic concentration ranging from 10% to 30% based on a total amount of first atoms of the first atom dopant and second atoms of the second atom dopant.

In accordance with some embodiments of the present disclosure, the metal-including intercalation material includes a metal halide.

In accordance with some embodiments of the present disclosure, the metal halide includes one of arsenic pentafluoride, antimony pentafluoride, iron (III) chloride, and combinations thereof.

In accordance with some embodiments of the present disclosure, an interconnect structure includes a conductive feature embedded in a dielectric feature and having a horizontal portion and a first vertical portion. The first horizontal portion extends in a horizontal direction to terminate at two edge surfaces, and includes graphene layers stacked on each other; and an intercalation material interposed among the graphene layers. The intercalation material includes a first atom dopant including one of a group 1 metal, a group 2 metal, a group 3 metal, a lanthanide series metal, an actinide series metal, and combinations thereof. The first vertical portion extends in a vertical direction and is in contact with one of the two edge surfaces of the first horizontal portion. The first vertical portion is made of a first electrically conductive metal material.

In accordance with some embodiments of the present disclosure, the first electrically conductive metal material includes ruthenium, copper, tungsten, titanium, aluminum, cobalt, molybdenum, iridium, rhodium, or combinations thereof.

In accordance with some embodiments of the present disclosure, the conductive feature further includes a second vertical portion extending away from the first vertical portion in the vertical direction.

In accordance with some embodiments of the present disclosure, the first horizontal portion has an upper surface and a lower surface opposite to the upper surface in the vertical direction. The conductive feature further includes a second horizontal portion which is in contact with one of the upper surface and the lower surface of the first horizontal portion, and which is made of a second electrically conductive metal material. The second horizontal portion extends in the horizontal direction and is in contact with the first vertical portion.

In accordance with some embodiments of the present disclosure, the second electrically conductive metal material includes ruthenium, copper, tungsten, titanium, aluminum, cobalt, molybdenum, iridium, rhodium, or combinations thereof.

In accordance with some embodiments of the present disclosure, an interconnect structure includes a conductive feature embedded in a dielectric feature, and has a first horizontal portion. The first horizontal portion includes graphene layers stacked on each other, and an intercalation material interposed among the graphene layers. The intercalation material includes a first atom dopant including one of a group 1 metal, a group 2 metal, a group 3 metal, a lanthanide series metal, an actinide series metal, and combinations thereof. First atoms of the first atom dopant between two adjacent ones of the graphene layers are arranged as a single atomic layer.

In accordance with some embodiments of the present disclosure, the intercalation material further includes a second atom dopant. A binding energy between the second atom dopant and the graphene layers is greater than a binding energy between the first atom dopant and the graphene layers. Between two adjacent ones of the graphene layers, the first atoms of the first atom dopant and second atoms of the second atom dopant are arranged as a single atomic layer.

In accordance with some embodiments of the present disclosure, between the two adjacent ones of the graphene layers, the first atoms of the first atom dopant and the second atoms of the second atom dopant are randomly distributed.

In accordance with some embodiments of the present disclosure, a space between the two adjacent ones of the graphene layers includes a central region and a boundary region surrounding the central region. The first atoms of the first atom dopant are disposed on the central region. The second atoms of the second atom dopant are disposed on the boundary region.

In accordance with some embodiments of the present disclosure, between the two adjacent ones of the graphene layers, two adjacent ones of the first atoms and the second atoms are spaced apart by an in-between distance. The in-between distance is not greater than an average bond length of third atoms and fourth atoms that are present in a bulk. The third atoms are of the same element as the first atoms, and the fourth atoms are of the same element as the second atoms

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnect structure, comprising a conductive feature embedded in a dielectric feature, and having a horizontal portion including
graphene layers stacked on each other; and
a metal-including intercalation material interposed among the graphene layers.

2. The interconnect structure according to claim 1, wherein the metal-including intercalation material includes a first atom dopant having one of a group 1 metal, a group 2 metal, a group 3 metal, a lanthanide series metal, an actinide series metal, and combinations thereof.

3. The interconnect structure according to claim 2, wherein the first atom dopant includes one of lithium, caesium, rubidium, calcium, sodium, strontium, barium, potassium, and combinations thereof.

4. The interconnect structure according to claim 2, wherein between two adjacent ones of the graphene layers, first atoms of the first atom dopant are arranged as a single atomic layer.

5. The interconnect structure according to claim 4, wherein two adjacent ones of the first atoms between two adjacent ones of the graphene layers are spaced apart by an in-between distance which is not greater than a bulk bond length of atoms that are present in a bulk and that are of the same element as the first atoms.

6. The interconnect structure according to claim 2, wherein the metal-including intercalation material further includes a second atom dopant, a binding energy between the second atom dopant and the graphene layers being greater than a binding energy between the first atom dopant and the graphene layers.

7. The interconnect structure according to claim 6, wherein the second atom dopant includes one of cobalt, chromium, vanadium, ruthenium, scandium, osmium, technetium, rhenium, tungsten, niobium, tantalum, hafnium, yttrium, and combinations thereof.

8. The interconnect structure according to claim 6, wherein the second atom dopant has an atomic concentration ranging from 10% to 30% based on a total amount of first atoms of the first atom dopant and second atoms of the second atom dopant.

9. The interconnect structure according to claim 1, wherein the metal-including intercalation material includes a metal halide.

10. The interconnect structure according to claim 9, wherein the metal halide includes one of arsenic pentafluoride, antimony pentafluoride, iron (III) chloride, and combinations thereof.

11. An interconnect structure, comprising a conductive feature embedded in a dielectric feature, and having
a first horizontal portion extending in a horizontal direction to terminate at two edge surfaces, and including
graphene layers stacked on each other, and
an intercalation material interposed among the graphene layers, the intercalation material including a first atom dopant including one of a group 1 metal, a group 2 metal, a group 3 metal, a lanthanide series metal, an actinide series metal, and combinations thereof, and
a first vertical portion extending in a vertical direction and being in contact with one of the two edge surfaces of the first horizontal portion, the first vertical portion being made of a first electrically conductive metal material.

12. The interconnect structure according to claim 11, wherein the first electrically conductive metal material includes ruthenium, copper, tungsten, titanium, aluminum, cobalt, molybdenum, iridium, rhodium, or combinations thereof.

13. The interconnect structure according to claim 11, wherein the conductive feature further includes a second vertical portion extending away from the first vertical portion in the vertical direction.

14. The interconnect structure according to claim 11, wherein:
the first horizontal portion has an upper surface and a lower surface opposite to the upper surface in the vertical direction; and
the conductive feature further includes a second horizontal portion which is in contact with one of the upper surface and the lower surface of the first horizontal portion, and which is made of a second electrically conductive metal material, the second horizontal portion extending in the horizontal direction and being in contact with the first vertical portion.

15. The interconnect structure according to claim 14, wherein the second electrically conductive metal material includes ruthenium, copper, tungsten, titanium, aluminum, cobalt, molybdenum, iridium, rhodium, or combinations thereof.

16. An interconnect structure, comprising a conductive feature embedded in a dielectric feature, and having a first horizontal portion including
graphene layers stacked on each other, and
an intercalation material interposed among the graphene layers, the intercalation material including a first atom dopant including one of a group 1 metal, a group 2 metal, a group 3 metal, a lanthanide series metal, an actinide series metal, and combinations thereof, first atoms of the first atom dopant between two adjacent ones of the graphene layers being arranged as a single atomic layer.

17. The interconnect structure according to claim 16, wherein:
the intercalation material further includes a second atom dopant, a binding energy between the second atom dopant and the graphene layers being greater than a binding energy between the first atom dopant and the graphene layers,
between two adjacent ones of the graphene layers, the first atoms of the first atom dopant and second atoms of the second atom dopant are arranged as a single atomic layer.

18. The interconnect structure according to claim 17, wherein between the two adjacent ones of the graphene layers, the first atoms of the first atom dopant and the second atoms of the second atom dopant are randomly distributed.

19. The interconnect structure according to claim 17, wherein a space between the two adjacent ones of the graphene layers includes a central region and a boundary region surrounding the central region,
the first atoms of the first atom dopant being disposed on the central region,
the second atoms of the second atom dopant being disposed on the boundary region.

20. The interconnect structure according to claim 17, wherein:
between the two adjacent ones of the graphene layers, two adjacent ones of the first atoms and the second atoms are spaced apart by an in-between distance; and
the in-between distance is not greater than an average bond length of third atoms and fourth atoms that are present in a bulk, the third atoms being of the same element as the first atoms, the fourth atoms being of the same element as the second atoms.
